(19) United States
(12) Patent Application Publication
(10) Pub. No.: US 2002/0140096 A1
(43) Pub. Date: Oct. 3, 2002

(54) Method and structure for ex-situ polymer stud grid array contact formation

(75) Inventor: Leo M. Higgins III, Austin, TX (US)

Correspondence Address: SCHIFF HARDIN & WAITE, 6600 SEARS TOWER, 233 S WACKER DR, CHICAGO, IL, 60606-6473, US

(73) Assignee: Siemens Dematic Electronics Assembly Systems, Inc.

(21) Appl. No.: 10/112,849

(22) Filed: Mar. 29, 2002

Related U.S. Application Data
(60) Provisional application No. 60/280,543, filed on Mar. 30, 2001.

(51) Int. Cl. H01L 21/44

(52) U.S. Cl. 257/737; 257/698; 438/652; 438/667

(57) ABSTRACT

A method and structure of ex-situ polymer stud grid array (ESWS-PSGA) contact formation on a semiconductor wafer having individual integrated circuit (IC) device areas. A large area of a polymer stud grid array (PSGA) field, including a polymer film, is pre-fabricated and then interconnected with the semiconductor wafer, and the ESWS-PSGA is formed using methods including laser structuring, compression molding, photolithographic-plasma etching, photolithographic processing, or adding material to the surface of the polymer film. The ESWS-PSGA has the PSGA field extend across the entire active surface of the semiconductor wafer, with metallized PSGA input/output (I/O) studs being disposed across the individual IC device areas. Alternatively, the ESWS-PSGA can be formed by spreading an extension of the polymer film beyond the perimeter of the semiconductor wafer, with metallized PSGA input/output (I/O) studs being disposed across the individual IC device areas. The extension provides temporary connection to an integrated circuit tester and/or an integrated circuit burn-in system, and may have studs for connecting to the tester.

### REFERENCE TO PROVISIONAL APPLICATION

This application claims benefit to U.S. provisional application No. 60/280,543, filed Mar. 30, 2001, which is incorporated herein by reference.

### BACKGROUND OF THE INVENTION

1. Field of the Invention

The present invention is generally directed to polymer stud grid arrays (PSGAs). In particular the present invention is directed to methods of forming ex-situ wafer scale—polymer stud grid arrays (ESWS-PSGAs), and structures formed using the methods.

2. Discussion of the Related Art

Wafer level packaging is in high demand due to miniaturization benefits. Formation of input/output (I/O) features on integrated circuit (IC) devices while still in wafer form is very desirable, since it allows for simpler IC-level testing and lower cost testing. In addition, wafer level packaging is more efficient because it eliminates packaging of each individual IC after wafer dicing. Moreover, “assembly” packaging processes are eliminated.

Wafer level test/burn-in is very efficient versus individual die test/burn-in when it comes to producing a Known Good Die (KGD). Because testing of individual bare die, or packaged die, requires numerous and costly testers and handlers, which spend a majority of time moving and handling the devices. In addition, bare IC or packaged component burn-in requires large areas, many testers, many sophisticated heated chambers, specialized equipment, and many expensive high temperature printed circuit boards and sockets.

Several competitive wafer level packaging methods and products are on the market at this time, most of which, if not all, use lead-tin solder balls for the I/O connection.

Wafer scale PSGAs provide the benefits mentioned above, plus benefits unique to PSGAs, such as lead-free fabrication, damage resistant I/O pads, stress compliant I/O for higher second level interconnect reliability, and contamination-free contact in testing because lead-tin solder ball oxides are not present, etc.

The ex-situ wafer scale—polymer stud grid array (ESWS-PSGA) of the present invention can be fabricated by several methods, which include various forms of compression molding, surface etching, and material additions to the surface of the film. A large area polymer stud grid array (PSGA) structure is pre-fabricated and then interconnected with the IC wafer.

Accordingly, two versions of ESWS-PSGA are described herein. In a first version, the PSGA field extends across the semiconductor wafer, with the PSGA input/output (I/O) studs disposed across each of the individual IC device areas. However, it is conceivable that the PSGA field extend across the entire semiconductor wafer, with the PSGA input/output (I/O) studs disposed across each of the individual IC device areas. In addition, the PSGA input/output (I/O) studs may also be located over desired test contact points that may lie between individual die, and in locations around the field of die.

In a second version, the PSGA field extends beyond the perimeter of the wafer. This polymer film extension is used for temporary connection to an IC tester, or an IC test/burn-in system. This extension may have studs for use in making contact to the tester, although other ways of connection to the tester, without the use of studs in the extension region, are conceivable.

### SUMMARY OF THE INVENTION

In accordance with one aspect of the present invention, a method for forming an ex-situ wafer scale polymer stud grid array comprising, providing a semiconductor wafer with integrated circuit device areas, the integrated circuit device areas having an array of input/output bond pads; coating a two-sided base film on at least one side with a polymer layer and forming raised studs in the polymer; forming a microvia through the base film and the polymer layer; applying a metal coating to the raised studs and the microvia; forming an interconnect circuit on the polymer layer; and bonding the semiconductor wafer to the metal coated raised studs.

In accordance with another aspect of the present invention, a method for forming an integrated circuit structure comprising, providing a semiconductor wafer with integrated circuit device areas having perimeter array of input/output bond pads; coating a two-sided base polymer film on at least one side with a polymer layer; forming raised polymer studs in the polymer layer; forming microvias in the base polymer film and the polymer layer; applying a metal coating to the raised polymer studs and the microvisas; forming an interconnect circuit on the polymer layer; and bonding the semiconductor wafer to the metal coated raised studs.

In accordance with a further aspect of the present invention, an ex-situ wafer scale polymer stud grid array structure formed on a semiconductor wafer having individual integrated circuit device areas thereon, the polymer stud grid array structure comprising, raised polymer studs in desired locations across the surface of the integrated circuit device areas; a metallization layer covering the raised polymer studs, the studs being disposed across each of the integrated circuit device areas in a grid array; an interconnect circuit on the polymer layer; and metallized microvias passing through the polymer layer.

These and other aspects of the invention will become apparent after careful review of the following detailed description of the presently preferred embodiments and accompanying drawings.

### BRIEF DESCRIPTION OF THE DRAWINGS

FIG. 1 shows a plan view of a region of a semiconductor wafer having nine die sites with perimeter input/output bond pads, in accordance with an exemplary aspect of the present invention;

FIGS. 2A-2O show schematic views of a cross-section of a base polymer film processed to form polymer studs, in accordance with exemplary aspects of the present invention;

FIG. 3A shows a finished semiconductor wafer before attachment of an ESWS-PSGA flex circuit stud field array, in accordance with an exemplary aspect of the present invention;

FIG. 3B shows a finished semiconductor wafer after attachment of an ESWS-PSGA flex circuit stud field array, in accordance with an exemplary aspect of the present invention;

FIG. 4A shows a cross-section view of a circuit film before formation of studs on a surface region, in accordance with an exemplary aspect of the present invention;

FIG. 4B shows a cross-section view of a circuit film after formation of studs on a surface region, in accordance with an exemplary aspect of the present invention;

FIG. 4C shows a cross-section view of a circuit film with metallized standard studs on one side, and contact pads on the opposing side for use in attachment to a bumped IC wafer, where standards studs will be used on individual die in connection to a printed circuit board having metallized pads, in accordance with an exemplary aspect of the present invention;

FIG. 5A shows a cross-section view of a circuit film and a surface region layer, in accordance with an exemplary aspect of the present invention;

FIG. 5B shows a cross-section view of a circuit film having standard studs on one side and small, low studs on the opposing side, in accordance with an exemplary aspect of the present invention;

FIG. 5C shows cross-section view of a circuit film having metallized microvias, metallized standard studs on one side for use in connection to a printed circuit board, and small, low metallized studs on an opposing side for connection to a semiconductor wafer, in accordance with an exemplary aspect of the present invention;

FIG. 6A shows a cross-section view of a circuit film and surface region layers, in accordance with an exemplary aspect of the present invention;

FIG. 6B shows a cross-section view of a circuit film having standard studs on one side and large, high studs on the opposing side, in accordance with an exemplary aspect of the present invention;

FIG. 6C shows a cross-section view of a circuit film having metallized microvias, metallized standard studs on one side for use in connection to a printed circuit board, and an opposing side having larger, higher metallized studs for connection to a semiconductor wafer, in accordance with an exemplary aspect of the present invention;

FIG. 7 shows a schematic view of a region of a semiconductor wafer exposing the stud side of a finished ESWS-PSGA flex circuit film after bonding to the semiconductor wafer, in accordance with an exemplary aspect of the present invention;

FIG. 8 shows a schematic of a region of a finished ESWS-PSGA flex circuit film that will be attached to a semiconductor wafer, in accordance with an exemplary aspect of the present invention;

FIG. 9 shows a schematic view of a PSGA stud array, with studs on both sides, joined to a semiconductor wafer by solder interconnect, in accordance with an exemplary aspect of the present invention;

FIG. 10 shows a schematic view of another two sided version a PSGA stud array with large studs on one side for joining to an interconnect substrate or PCB, and small studs on the other side that were joined to a semiconductor wafer by solder interconnect, in accordance with an exemplary aspect of the present invention;

FIG. 11 shows anisotropic conductive adhesive (ACA) between high studs on a ESWS-PSGA and a semiconductor wafer, in accordance with an exemplary aspect of the present invention; and

FIG. 12 shows anisotropic conductive adhesive (ACA) between low studs on a ESWS-PSGA and a semiconductor wafer, in accordance with an exemplary aspect of the present invention.

### DETAILED DESCRIPTION OF THE PRESENTLY PREFERRED EMBODIMENTS

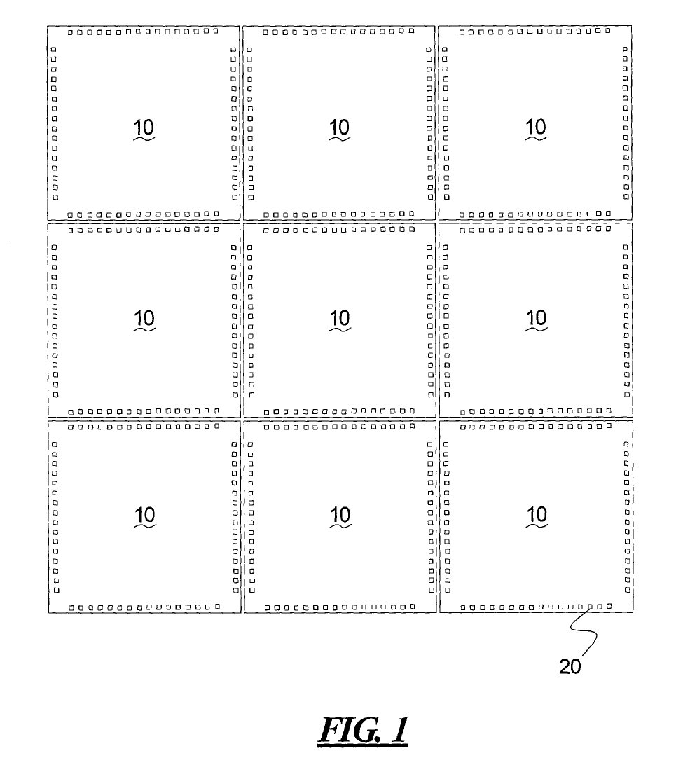

FIG. 1 shows a detailed plan view of a region of the semiconductor wafer 5 having nine die sites for integrated circuit (IC) devices areas 10. Each IC device area 10 has a perimeter array of the coated input/output (I/O) bond pads 20.

Coatings on the I/O bond pads 20 may include electroless nickel and gold; thin-film titanium and nickel and gold; thin film titanium and palladium; thin-film titanium/tungsten and gold; thin-film nickel/vanadium and gold; thin-film aluminum and nickel/vanadium and gold; thin-film chromium and chromium/copper and copper and gold, and the like. Use of a final gold, or other noble metal, layer optional since it is primarily an oxidation barrier layer.

The coatings provide high adhesion to a Al or Cu pad, provide a low ohmic resistance contact to a Al or Cu pad, provide a low ohmic resistance to subsequently applied metallurgies used in the creation of the ex-situ wafer scale polymer stud grid array (ESWA-PSGA). In addition, the coatings allow the total metal layer stack to resist corrosion, as well as prevent interface degradation due to excessive intermetallic formation and embrittlement, electromigration, and other stresses from environmental testing and the use environment.

Typically the pad-covering metallurgy extends beyond the pads 20 somewhat, and cover the bordering surface of IC passivation, which may overlay the perimeter region of the pad metallurgy.

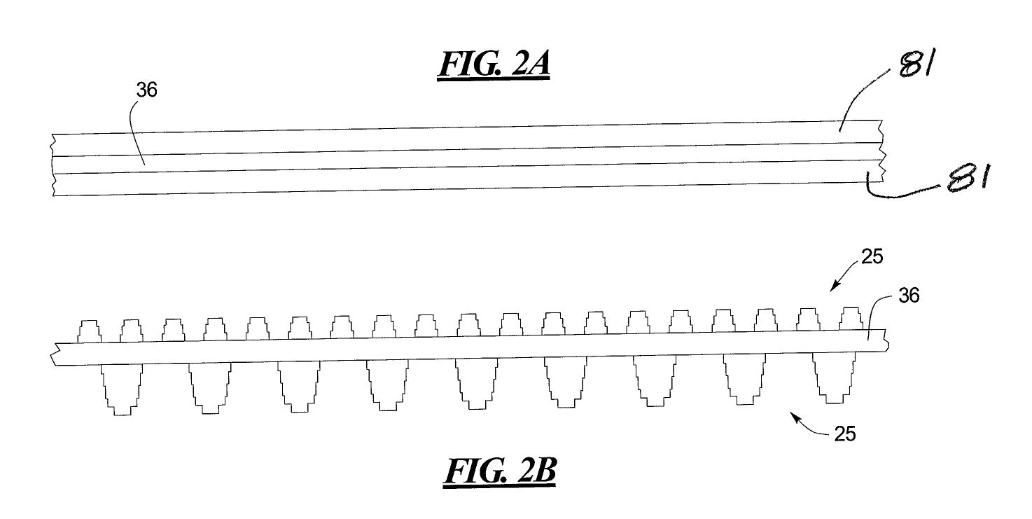

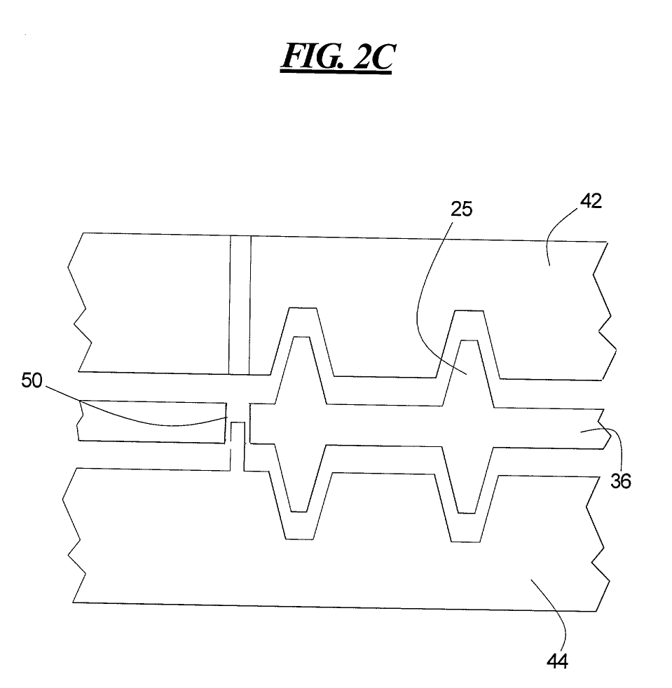

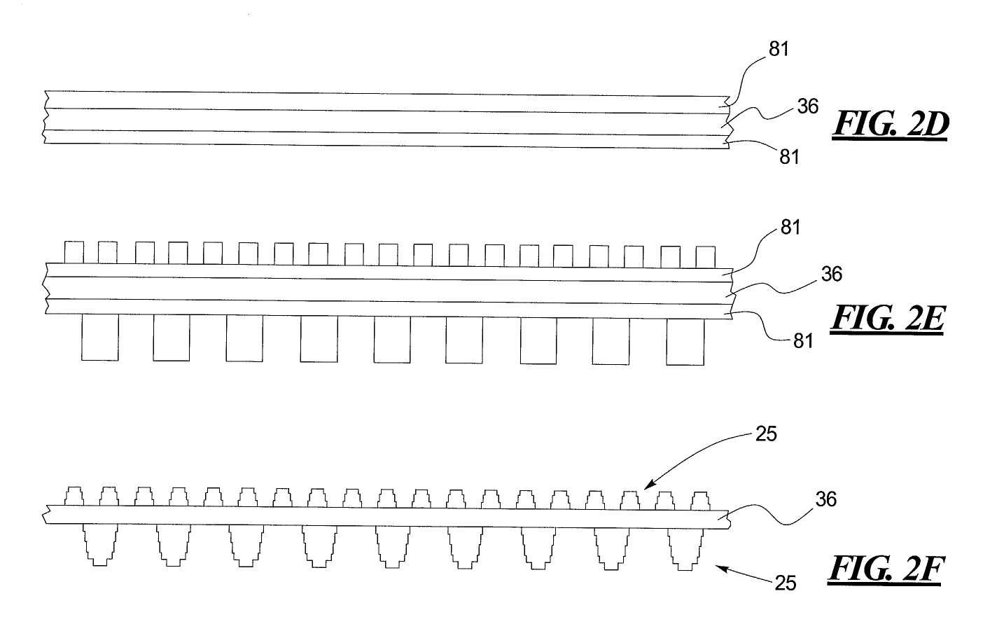

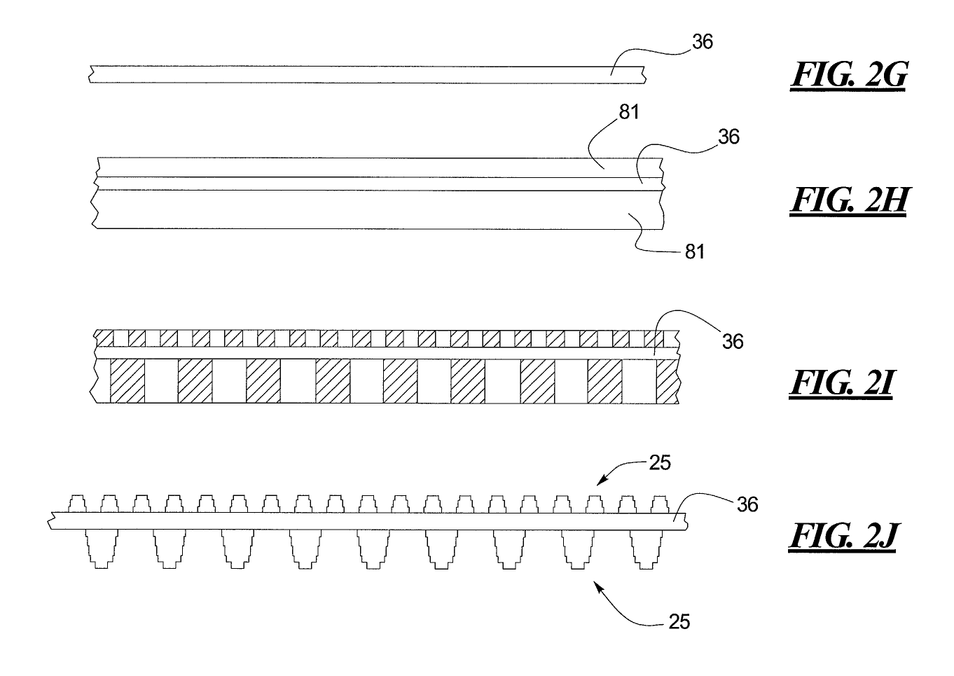

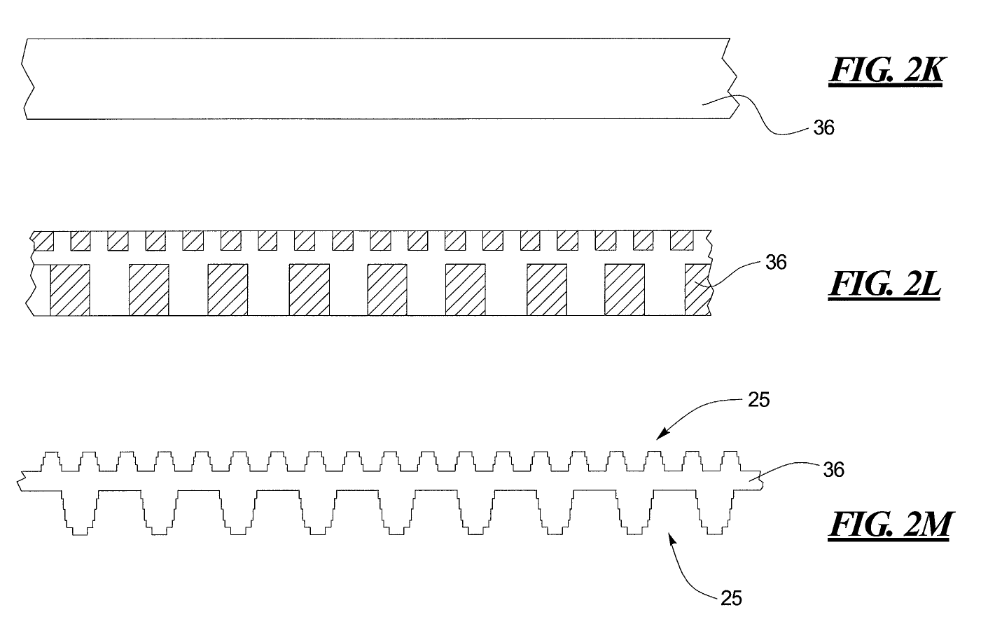

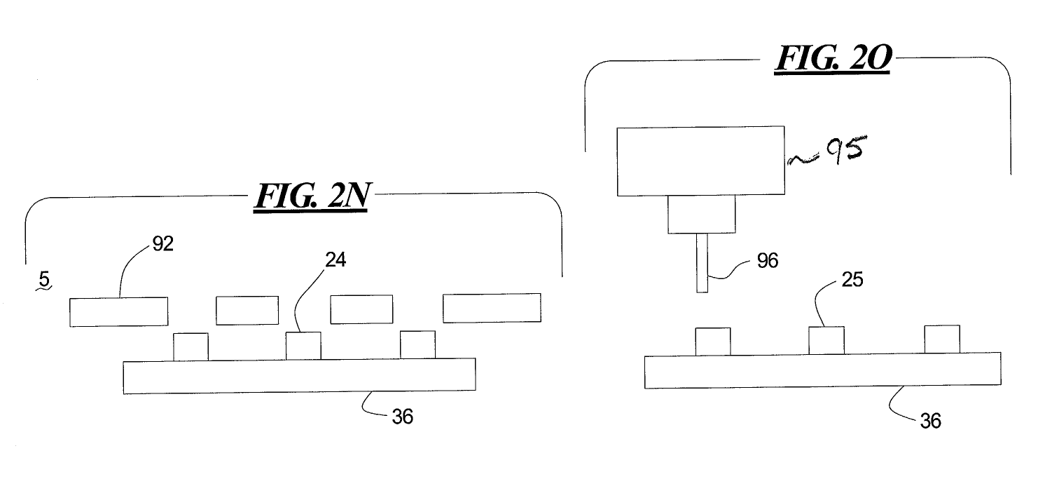

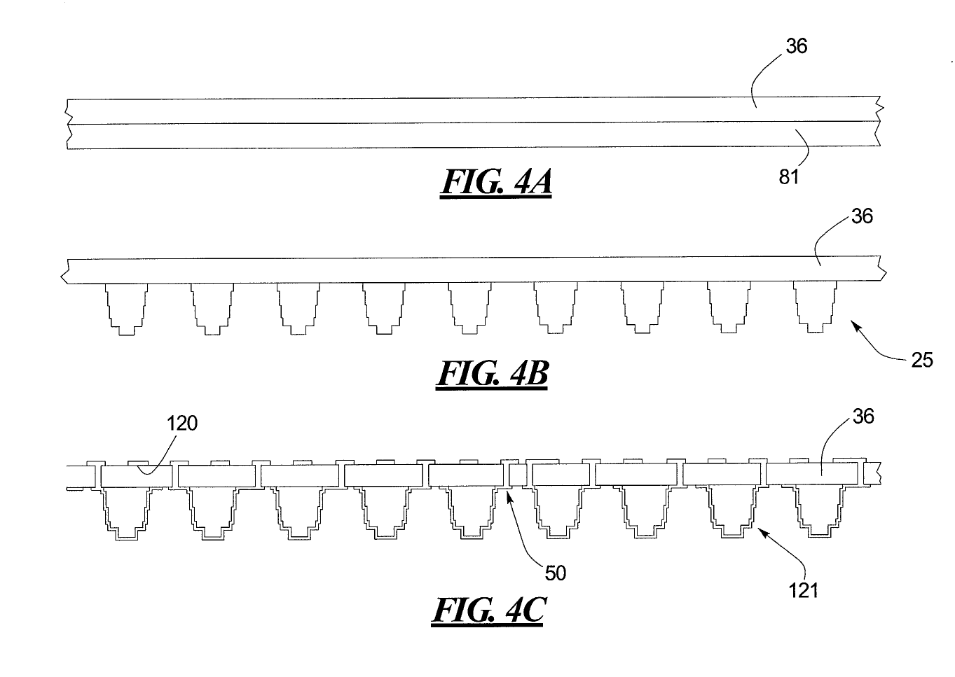

Fabrication methods for two versions of a base polymer film 36 on the ESWS-PSGA substrate in accordance with exemplary aspects of the present invention will now be discussed with reference to FIG. 2. The first version, hereinafter referred to as Type 1, is directed to wafer scale PSGAs, wherein the PSGA field extends across most of, or the entire semiconductor wafer 5, with metallized PSGA input/output (I/O) studs 121 (shown in FIG. 4C) disposed across each of the individual IC device areas 10. The second version, hereinafter referred to as Type 2, is directed to wafer scale PSGAs with a tester interface extension, wherein the PSGA field extends beyond the perimeter of the semiconductor wafer 5. The extension is used for temporary connection to an IC tester or an IC test/burn-in system, and may have metallized studs 121 (shown in FIG. 4C) for use in making contact to the tester, although other ways of connection to the tester are conceivable.

FIGS. 2A-2O show schematic views of a cross-section of base polymer film 36 that has been processed to form a polymer stud grid array on either one or both surfaces thereof. Either large studs or small studs can be formed on either or both surfaces of the base polymer film 36. The base polymer film 36 may alternatively be referred to herein as simply the film, the polymer film, the precursor flex film, the circuit film, or the core film.

In FIG. 2A, a base polymer film 36 is coated on each side with a surface layer 81 that will be processed to form the polymer studs 25 on respective sides of the film 36, prior to metal deposition and formation of desired conductor patterns 35 (as discussed with reference to FIGS. 7 and 8). The surface layers 81 may comprise a different material than the base polymer film 36, or each of the surface layers 81 may be homogeneous with the film 36.

FIG. 2B shows that the surface layers 81 on the base polymer film 36 have been processed to form the polymer studs 25. It is conceivable that the material comprising the surface layers 81, from which the studs 25 are formed, may be the same as or different from the material comprising the polymer film 36. In addition, the studs formed on either side of the film 36 can be processed from a homogeneous, single layer film. Exemplary methods of forming the studs 25 will be discussed herein.

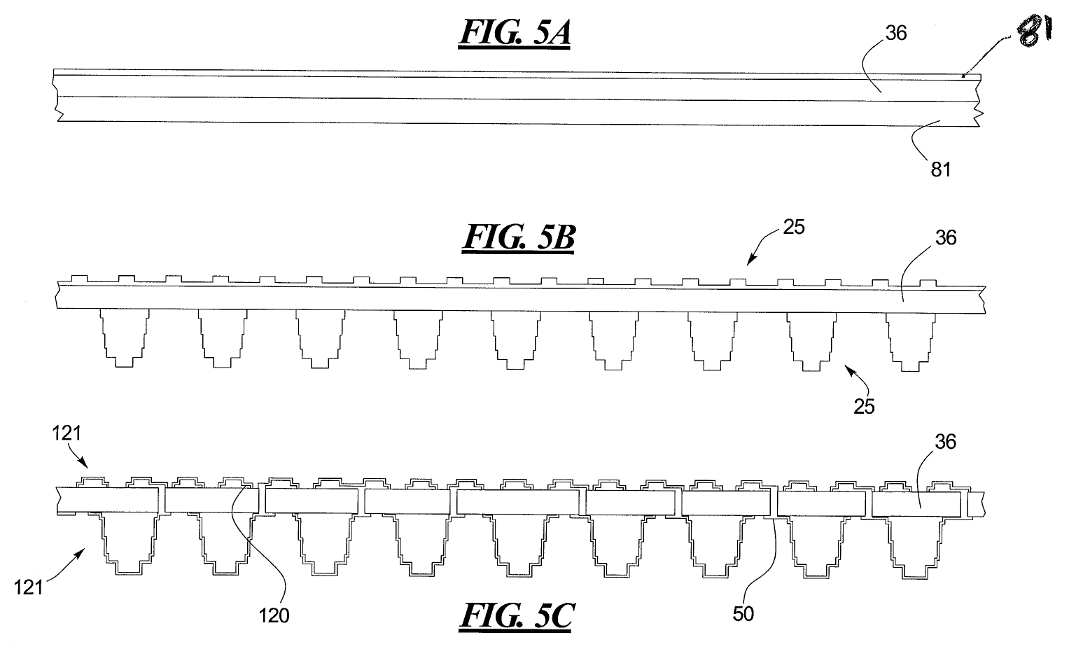

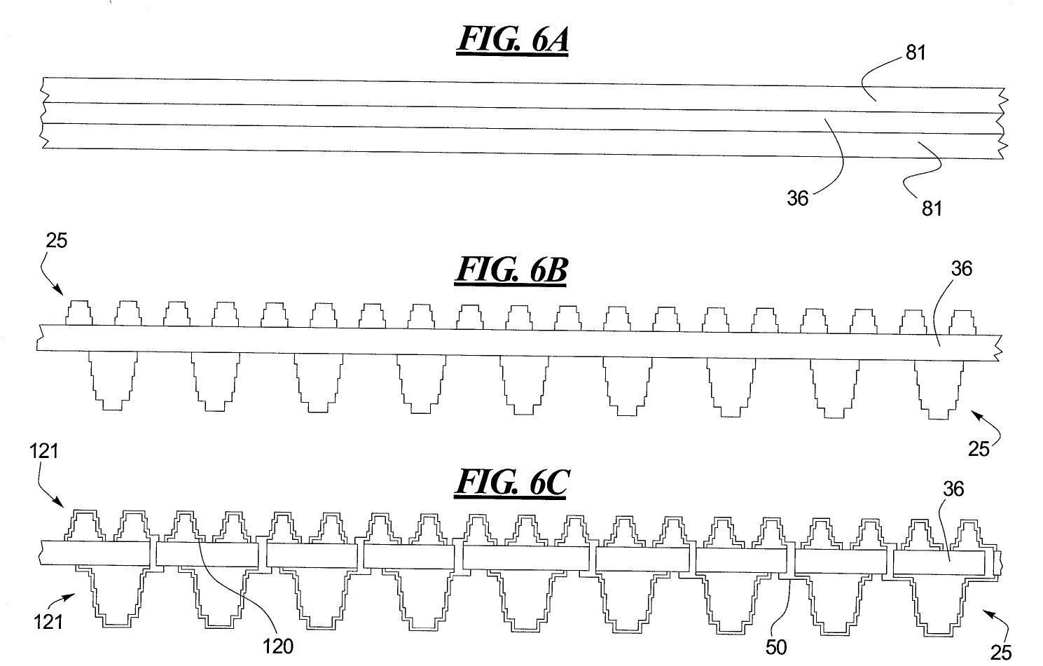

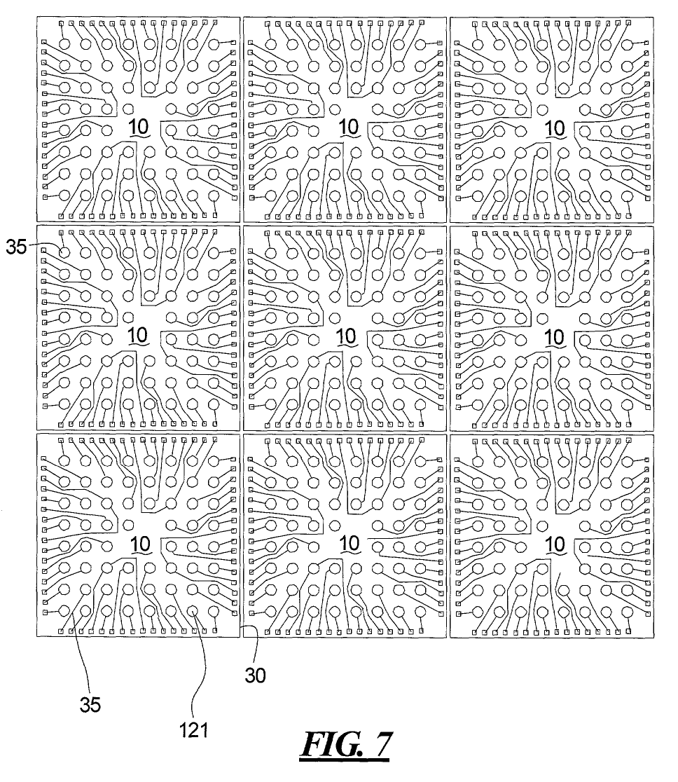

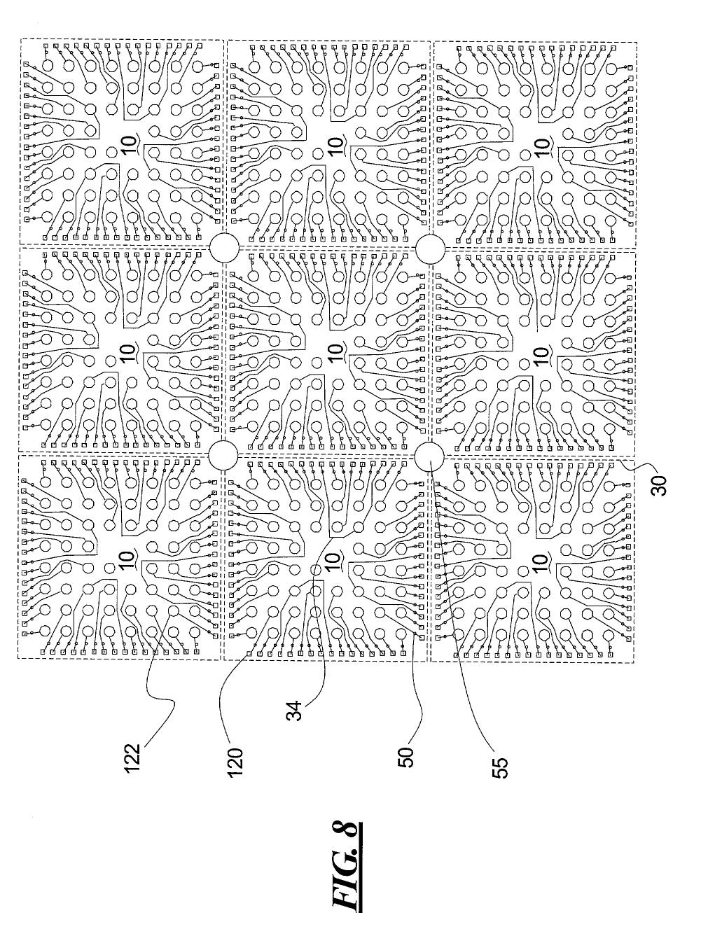

In FIG. 2B, large studs have been formed on one side of the polymer film 36, and small polymer studs have been formed on the other side of the same film. In the alterna-tive, large studs and small studs could have been formed on either or both surfaces of the base polymer film 36. Small metallized studs 121 (discussed with reference to FIGS. 5A-5C and FIGS. 6A-6C) are to be connected to bond pads of the individual IC device areas 10 (also discussed with reference to FIGS. 5A-5C, and large studs are for connection to a printed circuit board (PCB) (discussed with reference to FIGS. 6A-6C) after the finished ESWS-PSGA semiconductor wafer 5 is tested and individual ICs are singulated from the wafer 5.

The studded configurations of the base polymer film 36 discussed herein are only presented as exemplary aspects of the present invention and are shown here to illustrate the result of any process used to form the studs 25 on the film 36, and other studded configurations are conceivable.

An exemplary method of forming the studs 25 on the polymer film 36 shown in FIG. 2B is by laser structuring of the polymer film, wherein a computer-aided design data is loaded into a laser system computer control system. The laser system scans one or more laser beams across the surface of the polymer film 36, ablating polymer material comprising the film in desired locations, and thereby forming the stud grid array. The laser structuring could occur simultaneously to both sides of the polymer film 36, and regions that are not ablated become the studs 25. In reference to FIG. 4C, the laser is also used to form microvias 50 in desired locations on the film 36 across the stud array.

The laser may also form thinned regions about the perimeter of each of the IC device areas 10 on the semiconductor wafer 5, in the region of dicing streets 30, as seen in FIG. 7, if this is found to facilitate dicing of the finished ESWS-PSGA components after all assembly and testing has been performed.

Dicing streets or paths 30 are provided between each of the IC device areas 10. The thickness of polymer film coating 36 that overlies the dicing streets or paths 30 is formed to be thinner than polymer film 36 in other semiconductor wafer regions during formation of the polymer studs 25. The polymer coating 36 is formed to be thinner in the paths or streets 30 between the individual IC device areas 10 to minimize stress on the wafer 5, to improve dicing and to minimize stress due to thermal expansion differences between the wafer 5 and the polymer coating 36. Dicing may be performed in a number of methods including but not limited to excising with a laser, cutting with a mechanical saw blade, cutting with a water jet, cutting with a mechanical stamping tool, etc. The polymer film 36 may also be fully removed from the paths 30 to be followed by dicing saw blades, which facilitates handling and reduces the complexity of any subsequent dicing step needed to singulate the individual packaged IC components. Thus, the semiconductor wafer 5 can then be easily processed to dice the individual IC device areas 10 from the wafer 5, and the IC device areas 10 will be fully tested, or fully tested and burned-in, packaged integrated circuit components.

FIG. 2C shows a compression molding method of forming the polymer studs 25 on the polymer film 36 will now be discussed with reference to FIG. 2C.

According to the compression molding method, the polymer film 36 is hot-pressed between a top compression mold tool plate 42 and a bottom compression mold tool plate 44, each having complementary cavities in their respective surfaces reflecting the negative shape of the desired polymer studs 25 to be formed on both surfaces of the film 36. The compression mold tool plates 42, 44 could be flat surfaces (plate or polygonal roller) or in the form of cylindrical rollers. FIG. 2C shows the polymer film 36 after it has been subjected to elevated temperature and pressure by the plates 42, 44 to form the polymer studs 25 on both surfaces of the film 36.

With this method of forming polymer studs 25, the polymer film 36 deforms with the heat and pressure of the compression mold tool plates 42, 44. The polymer material comprising the film 36 is displaced and will flow into the cavities of the compression molding tool. When the mold tool is removed from the base polymer film 36, the studs 25 will be formed and the film between the studs will be thinned due to the displacement of material during the compression molding process. Using the compression molding process, it is also possible to form microvias 50 through the film 36 in desired locations.

The polymer film 36 may be a homogeneous material, or it may be a layered material. If the polymer film 36 is a layered material, a moldable material coating is provided on both surfaces of the film 36. However, if the polymer film 36 is a homogeneous material, then molding of the studs 25 is done on both sides of the film 36. Microvias 50 are then formed in the film 36 by laser drilling, mechanical punching, water jet, or by other means in desired locations.

Compression molding tools can be made by a variety of methods, such as mechanical machining or laser machining cavities in tools (plates, cavities, polygonal rollers, etc.), photolithographic etching of tools (plates, cylinders, polygonal rollers, etc.), bending etched plates about cylinders or polygonal rollers, etching cavities in Foto-Form Glass (a Corning product) plates, etching cavities in silicon wafers to from pyramidal cavities, etc.

Individual stud cavities in the compression molding tool may need vent holes, or the tool may be constructed such that the cavity vent hole is the diameter of the tip of the desired stud, or such that a closed volume above the tip of every stud 25 acts as a chamber into which cavity air is compressed during the compression molding process.

A further method of forming the studs 25 on the polymer film 36, termed photolithographic—plasma etching, is shown in FIGS. 2D-2F. This method involves coating the film 36 with a desired thickness of proper photodefinable polymer system, such as a photoresist. If the polymer studs 25 are desired on both surfaces of the polymer film 36, both surfaces are coated. If the studs 25 are to be formed on only one surface, only one surface need be coated.

Since the photoresist may have different thermomechanical properties than the film 36, it may be necessary to coat both surfaces thereof to allow the film 36 to remain flat after coating and processing. Since the film 36 is likely to be transmissive to the radiation used to expose the photoresist, the first side of the film 36, may need to be totally processed before the second side is coated.

FIG. 2D shows the base polymer film 36 coated on both sides. FIG. 2E shows base polymer film 36 after resist coating, exposure and developing, leaving only the resist material on the areas of the film 36 to be protected from the plasma etching, so as to leave only the raised studs 25 after ablation. After photoresist coating and a possible baking step, the photoresist surfaces are exposed to proper radiation through a mask which defines the regions to be exposed. The photoresist is developed, leaving small circular regions arrayed across the polymer film 36, in the locations where it is desired to form studs, then plasma etching of the entire surface is performed. The photoresist and the exposed base polymer film 36 are simultaneously etched, so the thickness and plasma etch rate of the photoresist must be capable of allowing the desired thickness of film 36 to be removed before the resist is totally removed.

FIG. 2F shows the base polymer film 36 after ablation and photoresist removal, leaving only raised polymer studs 25 on both sieds of the film 36 where the photoresist had been during the plasma etching. The shape of the studs shown in FIG. 2F are not specifically the shape that will result from such a process. The shape may vary depending on the materials used and the plasma etch process parameters.

Microvias 50 (not shown) are then formed in the film 36 by laser drilling, mechanical punching, water jet, or by other means, in desired locations. A metal film, such as electroless copper, nickel or tin can also be used as a resist, which may resist plasma etching better than an organic resist. Such a metal film may also be deposited by other thin film techniques, such as sputtering, chemical vapor deposition, or similar means. Another class of thin films that may used are oxide or nitride films, such as silicon nitride, silicon dioxide, and the like. These metal and ceramic films could be patterned with laser structuring or a preliminary photolithographic process sequence. Alternatively these films may be deposited through a mechanical mask to allow the metal or ceramic to be deposited only where desired, thus allowing a preliminary photolithographic process sequence to be avoided.

FIGS. 2G-2J show formation of polymer studs 25 by photolithographic processing, wherein a photopolymer coating on the film 36 becomes the stud material.

With this method, the base polymer film 36 is coated with a desired thickness of a proper photosensitive polymer system on both surfaces, if polymer studs 25 are desired on both surfaces of the film 36, as shown in FIG. 2H. However, if studs are to be formed on only one surface, only one surface of the film 36 need be coated (not shown). Since the photosensitive polymer may have different thermomechanical properties that the base polymer film 36, it may be necessary to coat both surfaces of the film 36 to allow the film 36 to remain flat after coating and processing. Furthermore, since the film 36 is likely to be transmissive to the radiation used to expose the photosensitive surface material, the first side of the base polymer film 36 may need to be totally processed before the second side is coated.

In FIG. 2I, the base polymer film 36 with the photosensitive polymer coating on both surfaces is shown after the photosensitive surfaces have been exposed through a mask to partially cure the exposed regions. Material volume exposed through phototooling is shown as cross-hatching.

FIG. 2J shows the film 36 after developing away unexposed material and finishing the cure of remaining photosensitive material, leaving only the polymer studs 25 attached to the film 36. Microvias 50 (not shown) are then formed by laser drilling in desired locations.

A negative-working photosensitive material, which does not allow exposed material to be removed after exposure, is shown in FIG. 2J. However, use of a positive-working material, in which the exposed material is removed during the developing step, is conceivable.

Use of a solid film of photosensitive material, other than base polymer film 36, along with careful phototool exposure from both sides of the film 36 followed by development of both sides, can lead to formation of polymer studs 25, according to an exemplary aspect of the present invention as will be discussed with reference to FIGS. 2K-2M.

Photolithographic processing of a film 36, which is comprised of a photosensitive material, is another method of forming the polymer studs 25 on the film 36, and will now be discussed with reference to FIGS. 2K-2M. With this method, the studs 25 are photolithographically processed from a film of photosensitive material.

FIG. 2K shows an initial photosensitive (PS) polymer film, which may be a free standing film, or may be carried on suitable films (such as polymer carrier films), or between suitable polymer films. Suitable carrier films posses proper optical properties to allow phototool exposure of the photosensitive film material directly through the carrier film.

The material volume exposed through phototooling is cross-hatched in FIG. 2L. The exposed PS film may need partial or full curing using thermal and/or radiative (such as ultraviolet radiation) curing before and/or after develop-ment to remove unexposed material.

In FIG. 2M, properly formed polymer studs 25 remain on both sides of the film 36, after developing away of unexposed material and finishing of the cure of remaining photosensitive material. The specific shapes of the studs and film plane surface shown in FIG. 2M are not a requirement of this invention. Microvias 50 (not shown) are then formed by laser drilling, mechanical punching, water jet, or by other appropriate means, in desired locations. FIG. 2M shows a negative-working photosensitive material, although use of a positive-working material is also conceivable.

In addition, the studs 25 can be formed in the base polymer film 36 by polymer deposition, as shown in FIGS. 2N and 2O. The studs 25 can be formed on one or both sides of the film 36 using this method, although FIGS. 2N and 2O show studs 25 being formed on only one side.

As shown in FIG. 2N according to this method, deposits 24 of a desired liquid or polymer paste material are stencil printed, using a stencil 92, onto the film 36. FIG. 2O shows deposits 24 of a desired liquid or polymer paste material are dispensed onto the film 36 using dispenser head 95 and dispenser needle 96. In either case, the deposit 24 is then cured to form the studs 25.

The desired polymer material may be a paste with or without particulate fillers added, and the base resin comprising the paste may be any type of epoxy, polyimide, bismaleimide-triazine, silicone, etc. Because the studs 25 formed using this method may be printed or dispensed on one or both sides of the film 36, the studs 25 may be the same size on both sides, or their sizes may be different (as discussed with reference to FIGS. 4A-4C and 5A-5C). The studs may be spaced apart on the same grid array on both sides of the film 36, or the grid array spacing may be different. The studs 25 may also be applied to the film 36 by other means, such as the transfer of preformed polymer studs from a carrier film to the polymer film 36, using a technique sometimes referred to as transfer printing, or lamination from a transfer tape.

Regardless of the method used to form the polymer studs 25 on the film 36, the studs 25 must be capable of being metallized, if the metallization deposition and formation of the conductors 35 (shown in FIGS. 7 and 8) follows formation of the polymer studs 25.

If the studs 25 are not capable of being metallized, they must be made conductive and solderable by virtue of the addition of appropriate conductive filler particles, such as metal, metallized polymer particles, metallized ceramic or glass particles, etc. If this type of stud is used, since it still must be capable of forming reliable, low resistance contacts with metallization on the film 36, the conductor pattern 35 on the film 36 will need to be formed first, and then the polymer studs 25 will be formed so as to land on top of the contacts and form on the film 36.

As used herein, the term “conductors” refers to any metallic element that is capable of conducting electricity (including metal coatings on the polymer studs 25, power and ground planes, metal on the microvias 50, etc.). A “conductor net” is an individual segment of conductors that runs from point A to point B, typically a narrow line whose length is much longer than its width, although it is also common to refer to a conductor net simply as a conductor. The term “conductor pattern” generally refers to a pattern formed by multiple conductor nets.

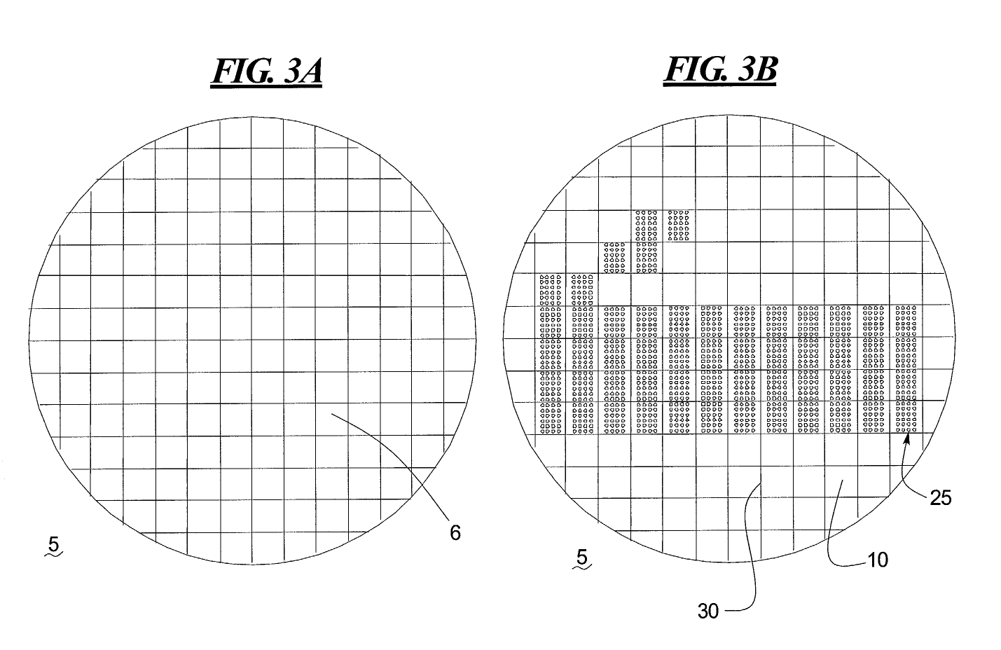

In reference to FIGS. 3A and 3B, a general process flow description of exemplary aspects of the present invention will now be given with respect to a semiconductor wafer 5 having an active side 6. Bond pads 20 (typically aluminum, but copper is beginning to be more common) formed on the wafer 5 are coated to prevent high contact resistance and corrosion in subsequent fabrication steps, environmental testing or in application environments. This coating is called Pad Cover Metallurgy (PCM). Metallization and circuit finishing of both versions (Type 1—Wafer Size, and Type 2 Wafer Size With Tester Interface Extensions) of an ESWS-PSGA substrate according to an exemplary aspect of the present invention will be discussed with reference to FIGS. 3A and 3B.

FIG. 3A shows a schematic view of the active device surface 6 of a finished semiconductor wafer 5 before attaching the ESWS-PSGA flex circuit array.

A base ESWS-PSGA substrate is prepared for application of metal by chemical etch, plasma etch, etc. First, vias 50, shown in FIG. 4C, may be formed through the film 36. The surface of the film 36 is activated and electroless Cu is applied, followed by deposition of electrolytic Cu. A desired metallized pattern of conductors 35 is then formed photolithographically, and the conductor pattern is insulated by the patterning of a resist on desired areas of the ESWS-PSGA. However, other methods of metallization and circuit finishing other than discussed herein are conceivable.

FIG. 3B shows a schematic view of the active device surface 6 of a finished semiconductor wafer 5 after attaching the ESWS-PSGA flex circuit stud field array. For purposes of simplicity, only the studs 25 are shown on portions of the stud field array.

Forming conductors 35 on the film 36 can be performed by either laser structuring, standard photolithographic, or other processes, and may be formed on the film 36 surfaces prior to bonding to the wafer 5.

For laser structuring (LS) of the conductors 35, electroless tin (Sn) is deposited on Cu surface, the desired conductor pattern is formed by laser structuring, wherein a scanned laser beam removes Sn and some underlying Cu in desired areas, Cu is etched in an ammonium copper chloride solution, and the Sn is stripped.

If subsequent Ni/Au plating is electroless, Cu conductors are isolated by the etch step. If subsequent Ni/Au is electrolytic, Cu conductors remain shorted to a plating buss bar on the ESWS-PSGA surface. Solder mask/plating resist is applied by stencil printing, spraying, etc., to both surfaces of ESWS-PSGA, filling microvias 50, and then desired openings are formed in the film 36 by photolithographic methods. Finishing metal (Ni plating, Sn plating, Au plating, etc.) is deposited on metal exposed in the solder mask openings. If electrolytic Ni/Au was used, a subsequent laser structuring step is required to expose the buss bar connections under the solder mask. These exposed connections are then etched away.

Standard photolithographic, and other process, may also be used to produce the conductors 35. Stencil printing or dispensing of the conductors 35 may also be used if the conductors 35 are formed before the studs 25 are formed on the film 36 through use of stencil printing or dispensing techniques.

Exemplary aspects of variations of the film 36 used for the ESWS-PSGA are shown in FIGS. 4A-4C.

FIG. 4A shows a cross-section view of a film 36 before formation of the polymer studs 25. The film 36 is overlaid on one side by a surface region which will be processed to form the polymer studs 25 on only that side thereof.

FIG. 4B shows a cross-section view of the film 36 after formation of standard sized polymer studs 25 on the only side of the film 36 overlaid by the surface region. The polymer film 36 has not yet been metallized in desired locations.

FIG. 4C shows a cross-section view of the film 36 after metallization of the polymer studs 25. The metallized studs 121 exist on only one side of the film 36, and are for use in connection to a PCB. Metallized pads 120 are formed in desired locations on the surface region of the film 36 using any conventional method, and metallized microvias 50 are also formed in desired locations. The other side of the film 36 is stud-free. In further exemplary aspects of the present invention, other arrangements of metallization and circuit finishing other than discussed herein are conceivable.

Formation of small, low studs on the film 36 will now be discussed with reference to FIGS. 5A-5C.

FIG. 5A shows a cross-section view of a film 36 before formation of the polymer studs 25 on both sides thereof. The polymer film 36 is overlaid by surface regions on both sides which will be processed to form the polymer studs 25.

FIG. 5B shows a cross-section view of the film 36 after formation of the studs 25 on both sides thereof, but before the film 36 has been metallized in desired locations. One side of the film has standard sized studs for making connection to a PCB, while the other side of the film 36 has small, low studs for connection to the semiconductor wafer 5. Neither the studs 25 or the polymer film 36 have been metallized in desired locations.

FIG. 5C shows a cross-section view of the film 36 after the polymer studs 25 on both sides thereof have been metallized. In addition to the metallized studs 121, the film 36 is provided with metallized microvias 50 in desired locations. The metallized microvias 50 are needed to connect the studs on one side of the film 36 with the metallized studs 121 on the other side of the film 36. In further exemplary aspects of the present invention, other arrangements of metallization and circuit finishing other than discussed herein are conceivable.

Formation of large, high studs on one side of the film 36 for connection to the PCB, and standard size studs formed on the opposing side of the film 36 for use in connection to a semiconductor wafer 5, will now be discussed with reference to FIGS. 6A-6C.

FIG. 6A shows a cross-section of the film 36 before formation of the polymer studs 25 on both sides thereof. The polymer film 36 is overlaid by surface region layers on both sides, which will be processed to form the polymer studs 25.

FIG. 6B shows a cross-section of the film 36 after formation of the studs 25 on both surface regions thereof. Standard sized studs 25 have been formed on one surface, while larger higher studs have been formed on the opposing surface. Neither the polymer studs 25 or the polymer film 36 have yet been metallized.

FIG. 6C shows a cross-section of the film 36 after metallization of the standard sized studs, which will be used to make connection to a semiconductor wafer 5, on one side of the film 36, and after metallization of the larger, higher studs, which will be used to make connection to the PCB. Metallized pads 120 in desired locations and metallized microvias 50 are provided. The metallized microvias 50 are needed to connect the studs on one side of the film 36 with the metallized studs 121 on the other side of the film 36. In further exemplary aspects of the present invention, other arrangements of metallization and circuit finishing other than discussed herein are conceivable.

The variations of stud formation shown in FIGS. 5A-5C and FIGS. 6A-6C are of interest because the cost to manufacture ESWS-PSGA films with studs on both sides is expected to be higher than a configuration with studs on only one side. Stud pitch (spacing) will impact such cost since smaller, more closely spaced studs will result in added complexity in routing desired conductors and in manufacturing, which further impacts costs. The height of the metallized studs 121 may impact the reliability of the connection to the IC device areas 10 or the semiconductor wafer 5, since lower studs may provide lower stress compliance, leading to reduction in connection reliability.

FIG. 7 shows a schematic view of a region of the active surface 6 of the semiconductor wafer 5 exposing the stud side of a finished ESWS-PSGA flex circuit film 36.

The studs 25 are shown for the IC device areas 10, with connections to conductors 35 arranged as conductor nets The microvias 50 and conductors 35 are covered with a solder mask material. Dicing streets or paths 30 are provided between each of the IC device areas 10. The streets or paths 30 are formed during formation of the polymer studs 25, such that the polymer coating 36 is formed to be thinner in the paths or streets 30 between the individual IC device areas 10. This is done to minimize stress on the wafer 5, to improve dicing and to minimize stress due to thermal expansion differences between the wafer 5 and the polymer coating 36. Dicing may be performed in a number of methods including but not limited to excising with a laser, cutting with a mechanical saw blade, cutting with a water jet, cutting with a mechanical stamping tool, etc. The polymer film 36 may also be removed from the paths 30 to be followed by dicing saw blades, which facilitates handling and reduces the complexity of any subsequent dicing step needed to singulate the individual packaged IC components. Thus, the semiconductor wafer 5 can then be easily processed to dice the individual IC device areas 10 from the wafer 5, and the IC device areas 10 will be fully tested, or fully tested and burned-in, packaged integrated circuit components.

FIG. 8 shows a schematic view of the surface detail of the region of the active surface of a semiconductor wafer 6 exposing the die side of a finished ESWS-PSGA flex circuit film 36. An outline of the metallized studs 121 on the opposing side of the film 36 is indicated, along with a metallized ESWS-PSGA bond pad 120 for bonding to a corresponding IC pad. An outline of the conductors 35 on the opposing side of the film 36 is shown in proximity to microvias 50. Optionally, an opening 55 for underfill dispense is provided in the film 36, and a solder mask material is provided to cover the microvias 50 and the conductors 35.

As discussed above with respect to FIG. 7, dicing streets 30 are provided between each of the IC device areas 10, and are formed during formation of the polymer studs 25, such that the polymer coating 36 is formed to be thinner in the paths or streets 30 between the individual IC device areas 10. Removal of polymer from the paths 30 facilitates handling and reduces the complexity of any subsequent dicing step needed to singulate the individual packaged IC components. The wafer 5 can then be easily processed to dice the individual IC device areas 10 from the wafer 5. Thus, the IC device areas 10 will be fully tested, or fully tested and burned-in, packaged integrated circuit components.

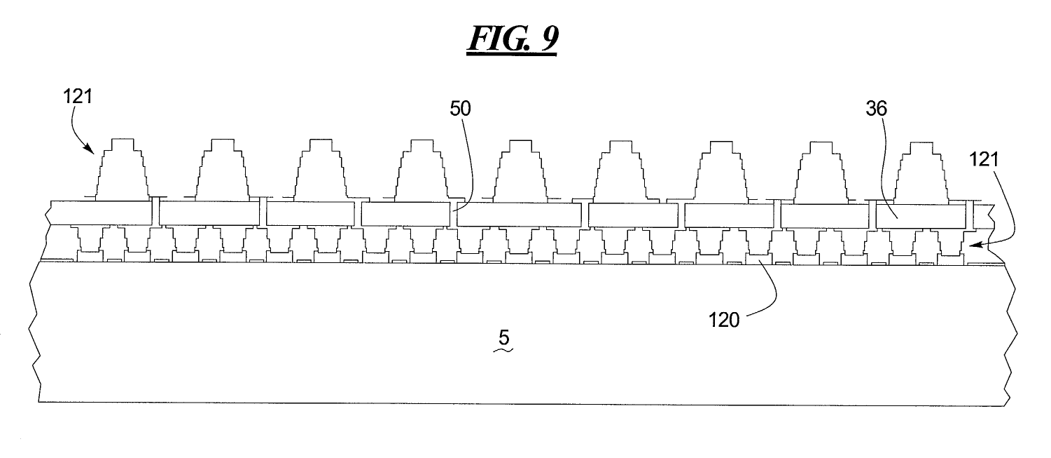

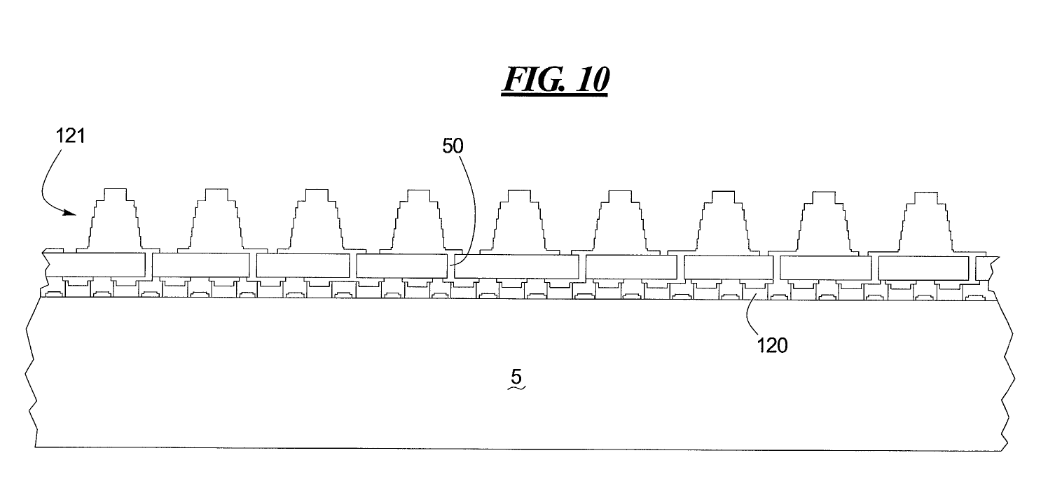

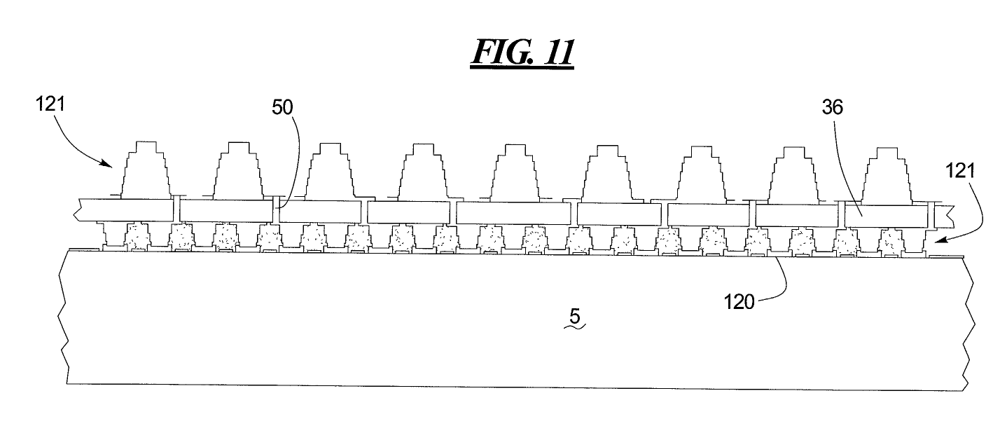

In accordance with exemplary aspects of the present invention, joining of the ESWS-PSGA film to the semiconductor wafer 5 can be performed by a variety of methods, which will now be discussed with reference to FIGS. 9 and 10.

FIG. 9 shows which shows exemplary examples of the two sided version the film 36 (discussed with reference to FIGS. 6A-6C) applied to the semiconductor wafer 5. The semiconductor wafer 5 is provided with an IC test and burn-in interface, and may involve either a bumped or unbumped die—to—PCB interconnect with integrated PSGA interposer as a wafer scale package. Electrically conductive material (such as solder, conductive adhesive, etc.) is disposed between the low studs, which have been metallized, and die pads. An insulating dielectric surrounds the metallized pads 120.

The polymer stud grid array can be joined to the semiconductor wafer 5 by using a solder interconnect, wherein a solder bumped wafer is connected to pads, low studs, large studs, etc., on the appropriate side of the polymer stud grid array. Solder paste is applied to the metallized pads 120, and appropriate IC device areas 10 are soldered to pads, low studs, large studs, etc. on the appropriate side of the polymer stud grid array. The polymer stud grid array may also have solder paste printed on it, or solder bumps formed on it, and then may be soldered to the IC device areas 10 which has had the metallized pads 120 processed to be solderable.

An alternative method of joining the ESWS-PSGA film to the semiconductor wafer 5 can be performed by using a conductive adhesive interconnect, as shown in FIG. 10.

FIG. 10 shows exemplary examples of the two sided version the film 36 (discussed with reference to FIGS. 5A-5C) applied to a semiconductor wafer 5. The semiconductor wafer 5 is provided with an IC test and burn-in interface, and either a bumped or unbumped die to PCB interconnect with an integrated PSGA interposer as a wafer scale package. Electrically conductive material (such as solder, conductive adhesive, etc.) is disposed between the low studs, which have been metallized, and die pads. An insulating dielectric surrounds the metallized pads 120.

Conductive adhesives may also be used to join the ESWS-PSGA film. In one method, B-staged conductive polymer bumps may be formed on the semiconductor wafer 5, and then the wafer 5 may be joined to the metallized pads 120, low studs, large studs, etc., on the appropriate side of the polymer stud grid array.

Alternatively, conductive polymer adhesive paste may be applied to the pads 20 on the wafer 5, then the polymer stud grid array is joined to the semiconductor wafer 5 and the paste is cured. In a variation of this method, the tips of low or high studs 121 may be coated with conductive epoxy with a roller-coater or a thin film applicator, or similar methods, and then the studded film is aligned in registry with the PCM-coated bond pads 20 and bonded to the wafer. B-staged conductive polymer bumps are formed on flat metal pads 120 on the side opposing the studs on the ESWS-PSGA film. Conductive adhesive paste may be applied to the PCMcoated bond pads 20 on the wafer 5, and then the studded film is joined to the wafer, and the B-staged bumps and the paste are cured. Alternatively conductive adhesive paste may be applied to the B-staged bumps with a roller coater or a thin film applicator or by other means and then the studded film is aligned to the PCM-coated bond pads 20 on the wafer and bonded together.

Details of the anisotropic conductive adhesive connection will now be given with reference to FIG. 11, which shows exemplary examples of anisotropic conductive adhesive (ACA) applied between metallized high studs formed on one side of the film 36 of the ESWS-PSGA for making connection to the semiconductor wafer 5. High metallized studs 121 are provided on the opposing side of the film for making connection to a PCB.

Anisotropic conductive adhesive (ACA) paste is applied either to the surface of the semiconductor wafer 5 or to the surface of the polymer stud grid array. Then, the polymer stud grid array and the semiconductor wafer 5 are aligned and pressed together for a desired time and at a specific temperature and pressure to cure the adhesive. If the ACA thickness and volume is not adequate to fill the gap between the wafer and the studded film, after adhesive cure it may be necessary to apply an encapsulant to fill this gap. The encapsulant may be introduced through holes 55 as exhibited in FIG. 8, or through other openings formed through the studded film opposing IC device areas 10.

If the ACA thickness and volume is sufficient it makes desired electrical connections and also fills gaps between the ESWS-PSGA film and the wafer 5 between the contacts. These filled volumes are non-conductive by nature of the properties of the ACA material. The ACA material may be in the form of a paste or a film sheet.

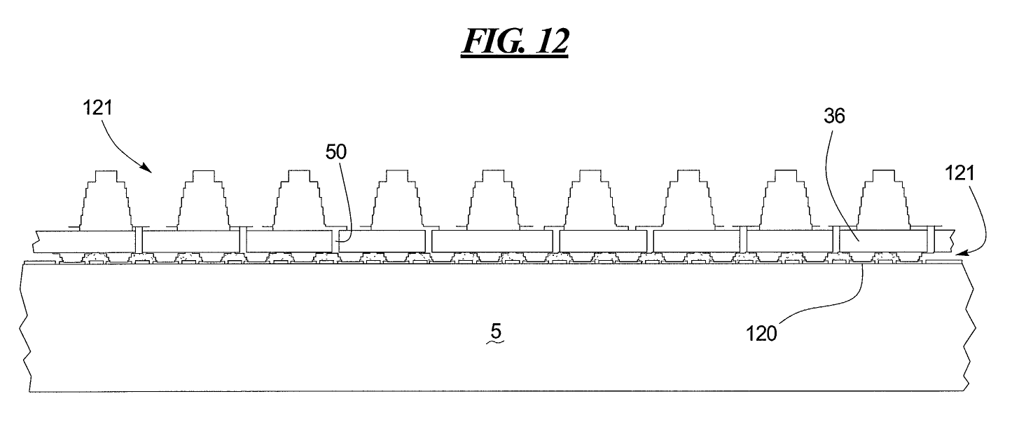

Further details of the anisotropic conductive adhesive connection will now be given with reference to FIG. 12, which shows exemplary examples of anisotropic conductive adhesive (ACA) applied between metallized low studs 121 formed on one side of the film 36 of the ESWS-PSGA for making connection to the semiconductor wafer 5. High metallized studs 121 are provided on the opposing side of the film for making connection to a PCB.

The anisotropic conductive adhesive joins the PSGA film and the semiconductor wafer 5 with conductive particles contacts between the metallized low studs 121 and the die pads.

The anisotropic conductive paste or adhesive film (ACF) may be applied or placed between the ESWS-PSGA film and the semiconductor wafer 5 prior to a heated pressure lamination process, wherein the polymer stud grid array and the semiconductor wafer 5 are aligned and pressed together for a desired time and at a specific temperature and pressure.

The ACF makes desired electrical connections and also fills gaps between the ESWS-PSGA and the wafer 5 between contacts. These filled volumes are nonconductive by nature of the properties of the ACF material.

It may be desirable to fill any existing gaps between the 36 of the ESWSPSGA and the semiconductor wafer 5 by underfilling, wherein a liquid encapsulant (typically epoxy or silicone elastomer-based polymer system) is dispensed into openings 55 (discussed with reference to FIG. 8) previously formed in the film 36.

Alternatively, the wafer may possess low bumps formed on bond pads 20. Such bumps may take the form of electroless nickel-gold plating or wire stud bumping. Such bumps may range from approximately 0.050 mm to 0.150 mm high, but may more typically be 0.080-0.100 mm in height. In this embodiment, the surface of the studded film to be joined to the wafer can be studless, and bond pads 120 can be flat. The ACA may be applied to either the surface of the wafer or the proper side of the studded film.

In further exemplary aspects of the present invention, other conductive materials, such as amalgams, may be used to join the polymer stud grid array and the semiconductor wafer 5.

Although modifications and changes may be suggested by those skilled in the art to which this invention pertains, it is the intention of the inventors to embody within the patent warranted hereon all changes and modifications that may reasonably and properly come under the scope of their contribution to the art.

What is claimed is:

1. A method for forming an ex-situ wafer scale polymer stud grid array, the method comprising:
providing a semiconductor wafer with integrated circuit device areas, the integrated circuit device areas having an array of input/output bond pads;
coating a two-sided base film on at least one side with a polymer layer and forming raised studs in the polymer;
forming a microvia through the base film and the polymer layer;
applying a metal coating to the raised studs and the microvia;
forming an interconnect circuit on the polymer layer; and
bonding the semiconductor wafer to the metal coated raised studs.

2. The method of claim 1, wherein the stud grid array extends substantially across the entire semiconductor wafer, with the metal coated studs disposed across each of the integrated circuit device areas.

3. The method of claim 1, wherein the stud grid array extends beyond the perimeter of the semiconductor wafer.

4. The method of claim 1, wherein the stud grid array is formed by one of laser ablation, compression molding or polymer deposition.

5. The method of claim 1, wherein the stud grid array is formed by coating the polymer film with a photodefinable polymer system, exposing the photoresist to radiation through a mask and etching away the photoresist.

6. The method of claim 1, wherein the interconnect circuit is formed by one of laser structuring or photolithography.

7. The method of claim 1, further comprising filling any existing gaps between the base polymer film and the semiconductor wafer.

8. The method of claim 1, further comprising, forming the raised studs on one side of the base polymer film.

9. The method of claim 1, further comprising forming the raised studs on both sides of the base polymer film.

10. The method of claim 1, further comprising bonding the semiconductor wafer to the metal coated raised studs by anisotropic conductive adhesive.

11. A method for forming an integrated circuit structure comprising:
providing a semiconductor wafer with integrated circuit device areas having perimeter array of input/output bond pads;
coating a two-sided base polymer film on at least one side with a polymer layer;
forming raised polymer studs in the polymer layer;
forming microvias in the base polymer film and the polymer layer;
applying a metal coating to the raised polymer studs and the microvisas;
forming an interconnect circuit on the polymer layer; and
bonding the semiconductor wafer to the metal coated raised studs.

12. The method of claim 11, further comprising filling any existing gaps between the base polymer film and the semiconductor wafer.

13. The method of claim 11, wherein the interconnect circuit is formed by one of laser structuring or photolithography.

14. The method of claim 11, further comprising, forming the raised studs on one side of the base polymer film.

15. The method of claim 11, further comprising forming the raised studs on both sides of the base polymer film.

16. The method of claim of claim 11, further comprising forming the raised polymer studs by one of laser ablation, compression molding or polymer deposition.

17. The method of claim 11, further comprising forming raised polymer studs by coating the base polymer film with a photodefinable polymer system, exposing the photoresist to radiation through a mask and etching away the photoresist.

18. The method of claim 11, further comprising bonding the semiconductor wafer to the metal coated raised studs by anisotropic conductive adhesive.

19. An ex-situ wafer scale polymer stud grid array structure formed on a semiconductor wafer having individual integrated circuit device areas thereon, the polymer stud grid array structure comprising:
raised polymer studs in desired locations across the surface of the integrated circuit device areas;
a metallization layer covering the raised polymer studs, the studs being disposed across each of the integrated circuit device areas in a grid array;
an interconnect circuit on the polymer layer; and
metallized microvias passing through the polymer layer.

20. The structure of claim 19, further comprising a two sided base polymer layer having the raised polymer studs formed on at least one side thereof.

21. The structure of claim 19, wherein the two-sided polymer layer has raised polymer studs formed on both sides thereof.
